(19) United States
(12) Patent Application Publication
(10) Pub. No.: US 2023/0061477 A1
(43) Pub. Date: Mar. 2, 2023

(54) SEALING SYSTEM FOR A REACTOR SYSTEM

(71) Applicant: ASM IP Holding B.V., Almere (NL)

(72) Inventors: Thomas Fitzgerald, Gilbert, AZ (US); Rohan Rane, Tempe, AZ (US); Jereld Winkler, Gilbert, AZ (US); Ankit Kimtee, Phoenix, AZ (US); Todd Robert Dunn, Cave Creek, AZ (US)

(21) Appl. No.: 17/895,370

(22) Filed: Aug. 25, 2022

Related U.S. Application Data
(60) Provisional application No. 63/238,324, filed on Aug. 30, 2021.

(51) Int. Cl. C23C 16/458; C23C 16/455

(52) U.S. Cl. CPC C23C 16/4583; C23C 16/45544; H01L 21/68742

(57) ABSTRACT

A reaction chamber may comprise a reaction chamber volume enclosed within the reaction chamber; a susceptor configured to support a substrate disposed in the reaction chamber volume; a reaction space above the susceptor, and a lower chamber space below the susceptor, within the reaction chamber volume; and/or a sealing system causing the reaction space and the lower chamber space to be at least partially fluidly separate. A sealing system may comprise a spacer plate surrounding and coupled to the susceptor; and/or a spring coupled to the spacer plate and the susceptor having a spring bias toward a compressed position or an extended position, such that the spring bias facilitates creation of at least a partial seal between the spacer plate and the susceptor, causing at least partial fluid separation between the reaction space and the lower chamber space as the susceptor moves up and down within the reaction chamber.

### CROSS-REFERENCE TO RELATED APPLICATIONS

This application is a nonprovisional of, and claims priority to and the benefit of, U.S. Provisional Patent Application No. 63/238,324, filed Aug. 30, 2021 and entitled “SEALING SYSTEM FOR A REACTOR SYSTEM,” which is hereby incorporated by reference herein.

### FIELD OF THE DISCLOSURE

The present disclosure relates generally to a semiconductor processing or reactor system, and particularly to a reactor system and to components comprised therein, which allow sealing between an upper and lower volume within a reaction chamber.

### BACKGROUND OF THE DISCLOSURE

Reaction chambers may be used for a variety of processes during formation of electronic devices. For example, reaction chambers can be used for depositing various material layers onto semiconductor substrates, etching materials, and/or cleaning surfaces. A substrate may be placed on a susceptor inside a reaction chamber. Both the substrate and the susceptor may be heated to a desired substrate temperature set point. In an example process, one or more reactant gases may be passed over a heated substrate, causing the deposition of a thin film of material on the substrate surface.

Reaction chambers may comprise two spaces or volumes that are separated, for example, by a susceptor. Processing may occur in a reaction space or chamber of the two chambers (e.g., an upper chamber that is disposed vertically above a lower chamber). During operation of a reactor system comprising two chambers separated by a susceptor, contaminants may undesirably transfer from the reaction space to the other chamber (e.g., from the upper chamber to the lower chamber). Therefore, systems and methods for providing a seal between the two volumes within the reaction chamber (e.g., to at least partially fluidly separate the two chambers) may be desirable.

Any discussion of problems and solutions involved in the related art has been included in this disclosure solely for the purposes of providing a context for the present disclosure, and should not be taken as an admission that any or all of the discussion was known at the time the invention was made.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, a reactor system is provided. The reactor system disclosed herein may facilitate at least partial sealing between two chambers or volumes within a reaction chamber of a reactor system.

In various embodiments, a reactor system may comprise a reaction chamber and/or a vacuum source in fluid communication with the reaction chamber (or a lower chamber space therein). A reaction chamber may comprise a reaction chamber volume enclosed within the reaction chamber; a susceptor configured to support a substrate disposed in the reaction chamber volume, the susceptor being configured to translate up and down along an axis within the reaction chamber; a reaction space above the susceptor within the reaction chamber volume; a lower chamber space below the susceptor within the reaction chamber volume; and/or a sealing system causing the reaction space and the lower chamber space to be at least partially fluidly separate. In various embodiments, a sealing system may comprise a spacer plate surrounding the susceptor, wherein the susceptor is coupled to the spacer plate; and/or a spring coupled to the spacer plate and the susceptor having a spring bias toward a compressed position or an extended position, such that the spring bias facilitates creation of at least a partial seal between the spacer plate and the susceptor, causing at least partial fluid separation between the reaction space and the lower chamber space as the susceptor moves up and down within the reaction chamber.

In various embodiments, the sealing system may further comprise a flow control ring disposed around the susceptor and disposed between the susceptor and the spacer plate. The spring may be disposed between the flow control ring and the spacer plate such that the spring is coupled to the susceptor via the flow control ring. The at least partial seal between the spacer plate and the susceptor may be facilitated by the spring bias between the flow control ring and the spacer plate. In various embodiments, the spring may be disposed between an upward-facing surface of the flow control ring and a downward-facing surface of the spacer plate. In various embodiments, the spring may be biased toward the extended position, such that a downward force from the spring is applied to the flow control ring, which creates a downward force on the susceptor, such that at least a partial seal is formed between the flow control ring and the susceptor, forming the at least partial fluid separation between the reaction space and the lower chamber space. In various embodiments, the spring may form at least a partial seal between the spring and the spacer plate, and between spring and the flow control ring. In various embodiments, the spring may be fixedly coupled to at least one of the spacer plate or the flow control ring.

In various embodiments, the spring may surround the susceptor. The spring may comprise a cross-sectional shape having at least one curl. In various embodiments, the cross-sectional shape of the spring may comprise an E-shape having three curls. In various embodiments, the spring may be disposed at a first point around the susceptor, wherein the reaction chamber further comprises a second spring disposed at a second point around the susceptor, such that a force on the susceptor resulting from the spring occurs at multiple points.

In various embodiments, a reaction chamber may further comprise a gas distribution device disposed above the susceptor in the reaction space, wherein the spring allows adjustment of a distance between the susceptor and the gas distribution device to be adjustable by up to nine millimeters while still maintaining the at least partial fluid separation between the reaction space and the lower chamber space.

In various embodiments, the spring may comprise at least one of a metal or metal alloy (e.g., stainless steel and/or a nickel alloy).

In various embodiments, a method may comprise translating a susceptor in a reaction chamber upwardly from a first position to a second position; applying a force on a spring coupled between the susceptor and a spacer plate in response to the moving the susceptor, wherein the spring has a spring bias toward a compressed position or an extended position; and/or maintaining at least a partial seal between the spacer plate and the susceptor during the moving the susceptor in response to the applying the force on the spring, such there is at least partial fluid separation between a reaction space above the susceptor and a lower chamber space below the susceptor in the reaction chamber. In various embodiments, the method may further comprise causing a downward force on the susceptor via the spring bias, which facilitates the at least partial fluid separation between the reaction space and the lower chamber space. In various embodiments, the force applied to the spring may comprise a compression force, and wherein the spring bias may be toward the extended position. In various embodiments, the reaction chamber may further comprise a flow control ring disposed between the susceptor and the spacer plate, wherein the spring is disposed between the flow control ring and the spacer plate such that the spring is coupled to the susceptor via the flow control ring.

In various embodiments, the method may further comprise moving an upward-facing surface of the flow control ring closer to a downward-facing surface of the spacer plate in response to the moving the susceptor, wherein the force applied on the spring is a compression force between the upward-facing surface of the flow control ring and the downward-facing surface of the spacer plate. In various embodiments, the method may further comprise maintaining at least a partial seal between the spring and the spacer plate, and between the spring and the flow control ring, during the moving the susceptor.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 is a schematic diagram of an exemplary reactor system, in accordance with various embodiments;

FIG. 2A is a schematic diagram of an exemplary reaction chamber with a susceptor disposed in a lower position, in accordance with various embodiments;

FIG. 2B is a schematic diagram of an exemplary reaction chamber with a susceptor disposed in a raised position, in accordance with various embodiments;

FIG. 3 illustrates a schematic diagram of a portion of a reaction chamber, in accordance with various embodiments;

FIGS. 4A and 4B illustrate schematic diagrams of a portion of a reaction chamber, in accordance with various embodiments;

FIG. 5 illustrates a spring for providing a seal within a reaction chamber, in accordance with various embodiments;

FIG. 6 illustrates another spring for providing a seal within a reaction chamber, in accordance with various embodiments; and

FIG. 7 illustrates a method for maintaining a seal within a reaction chamber, in accordance with various embodiments.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

As used herein, the term “substrate” may refer to any underlying material or materials that may be used, or upon which, a device, a circuit, or a film may be formed.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

As used herein, the term “contaminant” may refer to any unwanted material disposed within the reaction chamber that may affect the purity of a substrate disposed in the reaction chamber. The term “contaminant” may refer to, but is not limited to, unwanted deposits, metal and non-metal particles, impurities, and waste products, disposed within the reactor system or reaction chamber, or any portion thereof.

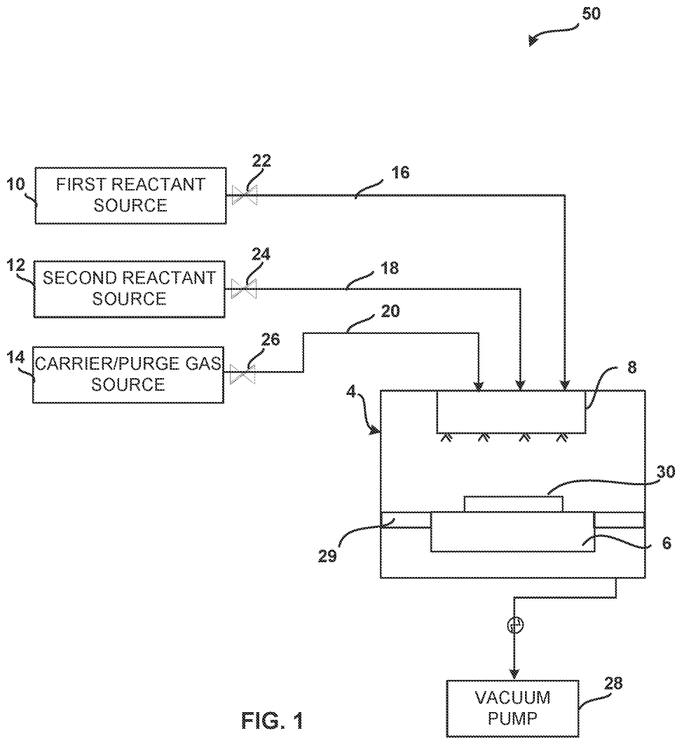

Reactor systems used for ALD, CVD, and/or the like, may be used for a variety of applications, including depositing and etching materials on a substrate surface. In various embodiments, with reference to FIG. 1, a reactor system 50 may comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16-20, and/or valves or controllers 22-26. System 50 may also comprise a vacuum source 28 fluidly coupled to the reaction chamber 4. Sealing members 29 may separate (e.g., at least partially separate fluidly) portions of a volume within reaction chamber 4.

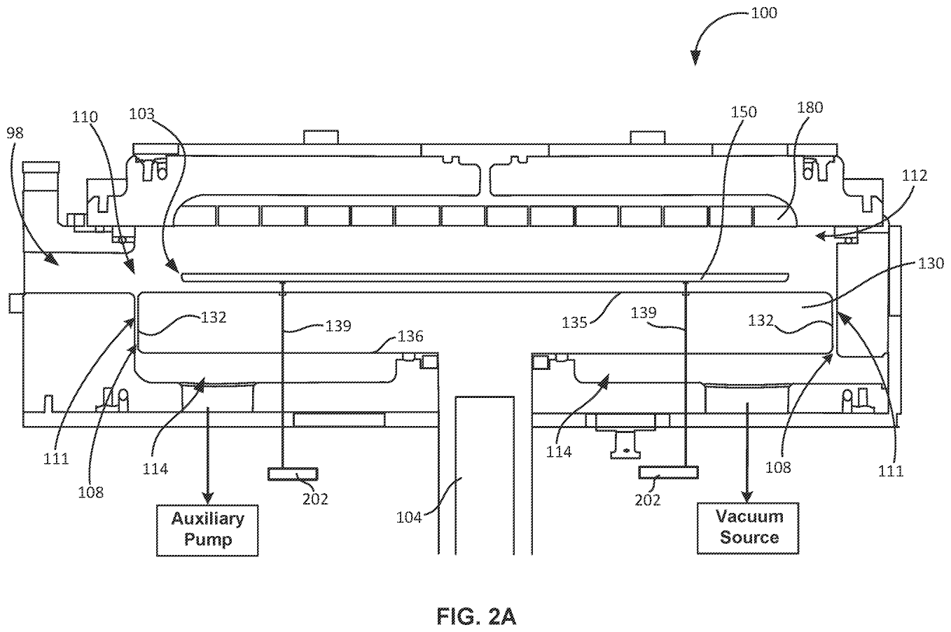

Turning to FIGS. 2A and 2B, the embodiments of the disclosure may include reactor systems and methods that may be utilized for processing a substrate within a reactor 100. In various embodiments, a reactor 100 may comprise a reaction chamber 110 for processing substrates. In various embodiments, reaction chamber 110 may comprise a reaction space 112 (i.e., an upper chamber), which may be configured for processing one or more substrates, and/or a lower chamber space 114 (i.e., a lower chamber). Lower chamber space 114 may be configured for the loading and unloading of substrates from the reaction chamber, and/or for providing a pressure differential between lower chamber space 114 and reaction space 112.

In various embodiments, substrate 150 and susceptor 130 may be movable relative to one another. For example, in various embodiments, lift pins 139 may be configured to allow substrate 150 to separate from susceptor 130, and to allow substrate 150 to be placed in contact with (i.e., to be supported by) susceptor 130. In various embodiments, susceptor 130 may move, for example via a susceptor elevator 104, up or down such that susceptor 130 moves relative to substrate 150. In various embodiments, lift pins 139 may move up or down, for example via lift pin elevators/platforms 202 such that substrate 150 moves relative to 130 susceptor. In various embodiments, susceptor 130 and/or lift pins 139 may be stationary while the other is moving. In various embodiments, susceptor 130 and/or lift pins 139 may be configured to move relative to the other.

In various embodiments, susceptor 130 may move from loading position 103 to processing position 106, thus moving substrate 150 into reaction space 112. Substrate 150 may be subsequently processed within the reaction chamber.

In various embodiments, reaction space 112 and lower chamber space 114 may be separated by a susceptor 130 disposed in reaction chamber 110. In various embodiments, reaction space 112 and lower chamber space 114 may be substantially fluidly separate or isolated from one another. For example, a susceptor 130 may fluidly separate reaction space 112 and lower chamber space 114 by creating at least a partial seal (i.e., at least restricting fluid flow) between susceptor 130 and a chamber sidewall 111 of reaction chamber 110 disposed proximate a susceptor outer side surface 132 of susceptor 130. That is, space 108 between susceptor 130 and chamber sidewall 111 may be minimized or eliminated such that there is little or no fluid movement between susceptor 130 and chamber sidewall 111.

In various embodiments, to prevent or reduce fluid flow between susceptor 130 and chamber sidewall 111, one or more sealing members (e.g., sealing members 129) may couple to susceptor 130 (e.g., from susceptor outer side surface 132) and/or chamber sidewall 111 of reaction chamber 110 to the other, creating at least a partial seal (i.e., restricting or preventing fluid flow) between susceptor 130 and chamber sidewall 111. Sealing members 129 may be diaphragms. The at least partial sealing of reaction space 112 from lower chamber space 114 may be desirable to prevent or reduce precursor gases, and/or other fluids, utilized in the processing of a substrate 150, from entering and/or contacting lower chamber space 114 of reaction chamber 110. For example, the precursor gases utilized for processing substrates in the reaction space may comprise corrosive deposition precursors, which may contact lower chamber space 114 producing unwanted deposits/contaminants/particles, which may in turn be reintroduced into reaction space 112 thereby providing a source of contamination to a substrate disposed in the reaction space.

In various embodiments, to create a seal between the reaction space and lower chamber space, a reaction chamber may comprise a sealing system disposed between the susceptor and the chamber sidewall. For example, the sealing system in reaction chamber 130 may comprise sealing member 129 disposed between susceptor 130 and chamber sidewall 111 to create at least a partial seal between reaction space 112 and lower chamber space 114.

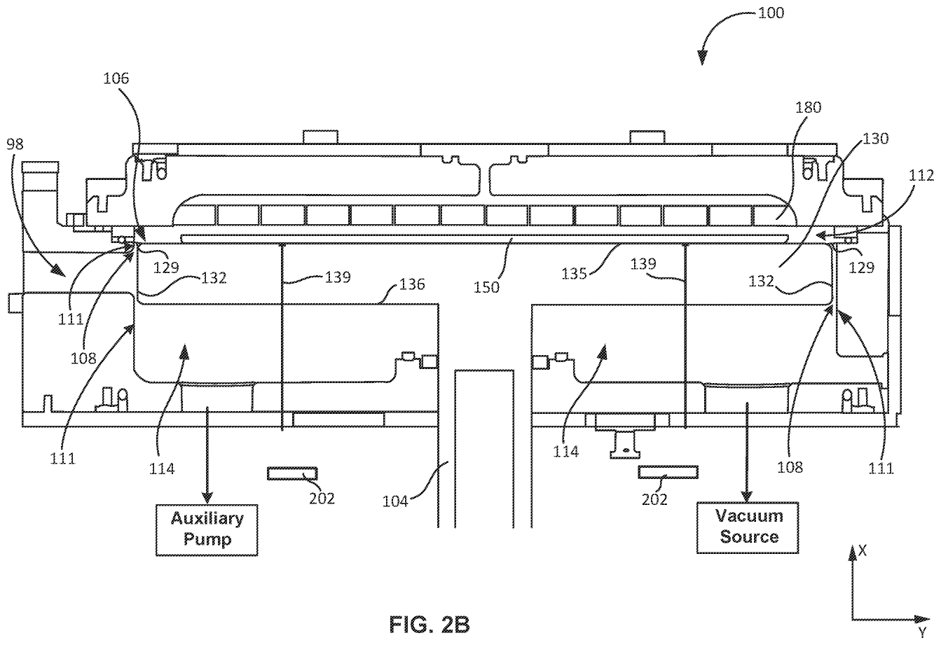

In various embodiments, a sealing system within a reaction chamber may comprise a spacer plate, at least a portion of which may be protruding from the chamber side wall into the reaction chamber volume. In various embodiments, the spacer plate may surround the susceptor in the reaction chamber. The spacer plate may couple with the susceptor (e.g., in response to the reaction chamber moving into or being disposed in a processing position (e.g., a raised position)). In various embodiments, the spacer plate maybe in contact with and/or coupled directly to the susceptor (e.g., when the susceptor is in the raised or processing position). For example, a downward-facing surface of the spacer plate (e.g., surface 374 in FIG. 3) may couple with and/or contact an upward-facing surface of the susceptor (e.g., upward-facing surface 336 in FIG. 3). In various embodiments, the upward-facing surface of the susceptor that may engage the spacer plate may be the substrate support surface.

In various embodiments, a sealing system in a reaction chamber may comprise a spring disposed between the spacer plate and the susceptor. In various embodiments, a spring may be disposed between a downward-facing surface of the spacer plate and an upward-facing surface of the susceptor. For example, a spring may be disposed at least partially between a downward-facing surface of the spacer plate that engages with an upward-facing surface of the susceptor. In various embodiments, a spring may be disposed between a downward-facing surface of the spacer plate and an upward-facing surface of a recess in the susceptor, in which at least a portion of the spring is disposed. In various embodiments, a spring may be disposed between a downward-facing surface of a recess in the spacer plate, in which at least a portion of the spring is disposed, and an upward-facing surface of the susceptor. In various embodiments, a spring may be disposed between a downward-facing surface of a recess in the spacer plate and an upward-facing surface of a recess in the susceptor.

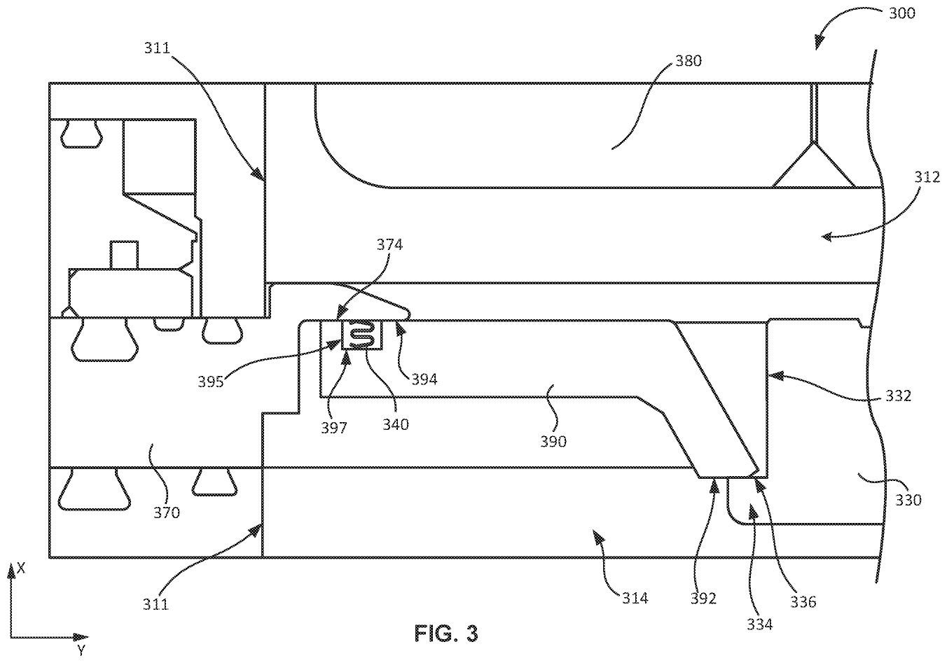

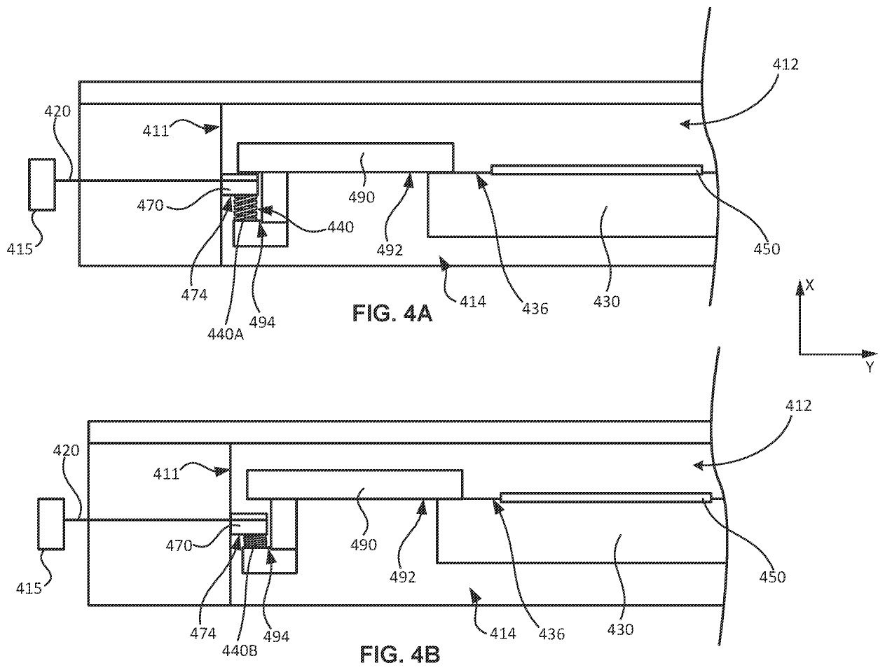

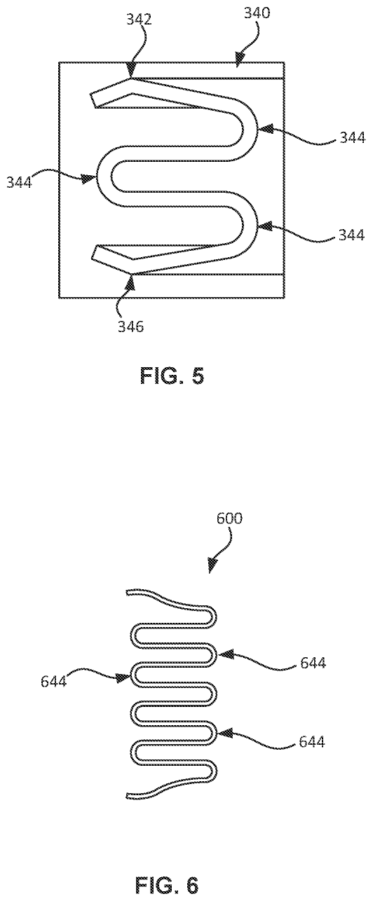

In various embodiments, a sealing system may comprise a flow control ring disposed between the susceptor and the spacer plate. A flow control ring may be disposed around the susceptor, and may be configured to control fluid flow within a reaction chamber. For example, sealing member 129 in FIG. 1 may be a flow control ring. Thus, the susceptor may be coupled to and/or engaged with the spacer plate via the flow control ring. The reaction space and the lower chamber space may be separated (fluidly and/or physically) by the susceptor, flow control ring, and/or spacer plate. For example, as shown in FIG. 3, flow control ring 390 may be disposed between spacer plate 370 and susceptor 330. Flow control ring 390 may comprise an upward-facing surface 394 that engages with (i.e., couples to and/or contacts) downward-facing surface 374 of spacer plate 370. Flow control ring 390 may comprise a downward-facing surface 392 that engages with (i.e., couples to and/or contacts) upward-facing surface 336 of susceptor 330. In various embodiments, the upward-facing surface of the susceptor with which flow control ring engages may be the substrate support surface. Similarly, as shown in FIGS. 4A and 4B, flow control ring 490 may be disposed between spacer plate 470 and susceptor 430. Flow control ring 490 may comprise an upward-facing surface 494 that engages with (i.e., couples to and/or contacts) downward-facing surface 474 of spacer plate 470. Flow control ring 490 may comprise a downward-facing surface 492 that engages with (i.e., couples to and/or contacts) upward-facing surface 436 of susceptor 430. In various embodiments, at least a portion of a flow control ring may be disposed above a spacer plate, such that the flow control ring cannot translate below the spacer plate.

In various embodiments, a spring may be disposed between the spacer plate and the flow control ring in a sealing system for a reaction chamber. In various embodiments, a spring may be disposed between a downward-facing surface of the spacer plate and an upward-facing surface of the flow control ring. For example, with reference to FIGS. 4A and 4B, a spring 440 may be disposed at least partially between downward-facing surface 474 of spacer plate 470 that engages with upward-facing surface 494 of flow control ring 490. In various embodiments, with reference to FIG. 3, a spring may be disposed between downward-facing surface 374 of spacer plate 370 and upward-facing surface 397 of recess 395 in flow control ring 390, in which at least a portion of spring 340 is disposed. In various embodiments, a spring may be disposed between a downward-facing surface of a recess in the spacer plate, in which at least a portion of the spring is disposed, and an upward-facing surface of the flow control ring. In various embodiments, a spring may be disposed between a downward-facing surface of a recess in the spacer plate and an upward-facing surface of a recess in the flow control ring.

In various embodiments, the inclusion of a spring in the sealing system of a reaction chamber may allow a seal to be formed that fluidly separates the reaction space and the lower chamber space within a reaction chamber volume over a range of heights of the reaction space. That is, a susceptor may be in a processing position (or a raised position) at a range of distances from a top of the reaction chamber volume (e.g., a fluid distribution system), while still creating a seal with the other components of the reaction chamber sealing system (e.g., a spacer plate and/or a flow control ring).

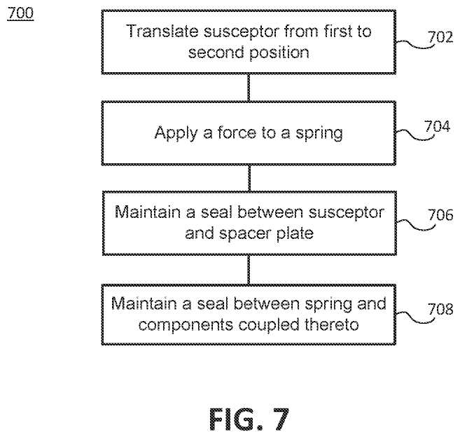

In operation, with reference to method 700 shown in FIG. 7, the susceptor may translate from a first position (e.g., a lower position or loading position) to a second position (e.g., a raised position or processing position) (step 702). In the lower position, the susceptor may not be in contact with any other component of the sealing system of the reaction chamber (e.g., a spacer plate and/or a flow control ring). Accordingly, a lower chamber space and a reaction space within the reaction chamber volume may be in fluid communication. A spring in the sealing system may be in a relaxed position (e.g., for a spring biased toward an uncompressed or extended position, such a spring may be in an uncompressed or less compressed position). The susceptor may translate along the x-axis depicted in FIGS. 3 and 4A-4B toward a raised position (e.g., a processing position). The processing position of a susceptor may be the position at which the susceptor is disposed (e.g., at a desired distance from the top or fluid distribution system of the reaction chamber) during processing of the substrate. During translation, an upward-facing surface of the susceptor may engage with and/or couple to a downward-facing surface of the sealing system, such as a downward-facing surface of a spacer plate and/or a flow control ring.

In response to the susceptor engaging with the spacer plate and/or flow control ring, a force may be applied to the spring in the sealing system (step 704), which may be moved against its bias (e.g., compressed). Thus, the spring may apply a force on the components between which the spring is disposed. For example, the spring may apply an upward force on the spacer plate and a downward force on the flow control ring and/or the susceptor. The downward force from the compressed spring (against its bias) on the flow control ring may press the flow control ring into the susceptor. Thus, at least a partial seal may be formed between the spacer plate and the susceptor (step 706) via the flow control ring (i.e., at least a partial seal may be formed directly between the flow control ring and the susceptor). Such an at least partial seal may be maintained in response to the susceptor reaching and being disposed in the processing position and throughout substrate processing. In various embodiments, at least a partial seal may be maintained between the spring and the components to which the spring is coupled (step 708) (e.g., maintaining at least a partial seal between the spring and the spacer plate, and/or between the spring and the flow control ring). Accordingly, in the reaction chamber volume, the lower chamber space may be at least partially fluidly isolated from the lower chamber space.

With reference to FIG. 3, in operation, susceptor 330 may translate along the x-axis from a lower position to a raised position. Susceptor 330 may not be in contact with flow control ring 390 in the lower position. As susceptor 330 contacts and/or engages with flow control ring 390, spring 340 may be compressed from a relaxed position to a compressed position. Spring 340 may be biased toward an uncompressed or less compressed position. Spacer plate 395, and/or the portion thereof protruding from chamber sidewall 311, may be substantially static (i.e., spacer plate 390 and portions thereof do not move in response to a force by spring 340). In response to compression of spring 340, spring 340 may exert an upward force on downward-facing surface 374 of spacer plate 370, and/or a downward force on upward-facing surface 397 of flow control ring 390. In response, flow control ring 390 may exert a downward force on upward facing surface 336 of susceptor 330. Upward-facing surface 336 may be comprised in susceptor protrusion 334 protruding from susceptor outer side surface 332. In various embodiments, the upward-facing surface of the susceptor receiving the downward force from the spring and/or flow control ring may be comprised on a substrate support surface of the susceptor. The downward force of flow control ring 390 on susceptor 330 may cause at least a partial seal to be formed between flow control ring 390 and susceptor 330. Thus, reaction space 312 and lower chamber space 314 may be at least partially fluidly separate.

With reference to FIGS. 4A and 4B, in operation, susceptor 430 may translate along then x-axis from a lower position to a raised position. Susceptor 430 may not be in contact with flow control ring 490 in the lower position. As susceptor 430 contacts and/or engages with flow control ring 490, spring 440 may be compressed from a relaxed position 440A to a compressed position 440B. Spring 440 may be biased toward an uncompressed or less compressed position. Spacer plate 490, and/or the portion thereof protruding from chamber sidewall 411, may be substantially static (i.e., spacer plate 490 and portions thereof do not move in response to a force by spring 440). In response to compression of spring 440, spring 440 may exert an upward force on downward-facing surface 474 of spacer plate 470, and/or a downward force on upward-facing surface 494 of flow control ring 490. In response, flow control ring 490 may exert a downward force on upward-facing surface 436 of susceptor 430. In various embodiments, the upward-facing surface of the susceptor may be comprised on a substrate support surface of the susceptor. The downward force of flow control ring 490 on susceptor 430 may cause at least a partial seal to be formed between flow control ring 490 and susceptor 430. Thus, reaction space 412 and lower chamber space 414 may be at least partially fluidly separate.

In various embodiments, the spring may form at least a partial seal between the components to which the spring is coupled. For example, with reference to FIG. 3, spring 340 may form at least a partial seal between spacer plate 370 and flow control ring 390. Such an at least partial seal may be formed by the bias of the spring 340 toward an uncompressed or less compressed position, such that the upward force of spring 340 on spacer plate 370, and the downward force of spring 340 on flow control ring 390, create at least partial seals between spring 340 and spacer plate 370 and/or flow control ring 390. As another example, with reference to FIGS. 4A and 4B, spring 440 may form at least a partial seal between spacer plate 470 and flow control ring 490. Such an at least partial seal may be formed by the bias of the spring 440 toward an uncompressed or less compressed position 440A, such that the upward force of spring 440 on spacer plate 470, and the downward force of spring 440 on flow control ring 490, create at least partial seals between spring 440 and spacer plate 470 and/or flow control ring 490.

In various embodiments, the spring of a sealing system in a reaction chamber may be coupled (e.g., fixedly coupled via welding, adhesive, or the like) to the components between which the spring is disposed. For example, the spring of a sealing system in a reaction chamber disposed between a spacer plate and a susceptor may be coupled to the spacer plate and/or the susceptor. As another example, the spring of a sealing system in a reaction chamber disposed between a spacer plate and a flow control ring may be coupled to the spacer plate and/or the flow control ring.

An at least partial seal between the susceptor and spacer plate and/or flow control ring in a reaction chamber may be achieved over a range of susceptor positions (i.e., over a range of distances of the susceptor from the top or fluid distribution system of the reaction chamber). The spring allows engagement between the susceptor and the spacer plate and/or the flow control ring at a position lower than the upward-most position of the susceptor (i.e., the position of the susceptor such that the reaction space is the shortest between the susceptor and the top of the reaction chamber or the fluid distribution system). Thus, the downward force cause by the spring on the susceptor in any position in which the susceptor is engaged with the spacer plate and/or flow control ring causes at least partial a seal between the spacer plate and/or flow control ring and the susceptor over the spring's range of compression.

In various embodiments, a spring may comprise a shape that surrounds the susceptor in a reaction chamber. For example, spring 340 in FIG. 3 may span all the way around susceptor 330. In various embodiments, a spring may be disposed at one or more points around the susceptor, such that the force on the susceptor that creates a seal in the reaction chamber may occur at multiple points around the susceptor.

In various embodiments, a spring may comprise a cross-sectional shape comprising at least one curl. For example, spring 340 in FIG. 3 may comprise an E-shaped cross-sectional shape, which has three curls 344 between first end 342 and second end 346. A spring may comprise any suitable number of curls depending on the desired height of the spring and the desired flexibility of the components within a reaction chamber. For example, spring 600 may comprise more than three curls 644.

In embodiments without a spring, the components of a reaction chamber must be manufactured and fit together with precision, such that there is little or no room for any variation in part shape or position (e.g., surfaces must be angled a certain way). This increases manufacturing time and costs and the potential for error (e.g., components not fitting together correctly, failing to create a seal between the reaction space and the lower chamber space, causing contaminants to flow into the lower chamber space, etc.). Additionally, the reaction space height (e.g., the distance from the upper susceptor surface (i.e., the substrate support surface) to the fluid distribution system) may be fixed such that such distance cannot be adjusted without compromising the fit between components and the seal provided thereby). On the other hand, the presence of a spring in a reaction chamber sealing system allows for less precision in component design, manufacture, and/or position for components to engage one another and create a seal therebetween to at least partially fluidly separate the reaction space from the lower chamber space. For example, the susceptor may be slightly tilted, and the susceptor may still sufficiently engage with the spacer plate and/or flow control ring. Also, the reaction space height (i.e., the distance between the susceptor and the fluid distribution system) may be adjustable while still maintaining a seal between the reaction space from the lower chamber space. Therefore, the reaction space height may be adjusted depending on the process taking place and the desired space between the substrate and the fluid distribution system.

In various embodiments, for a spring comprising an E-shape (as shown in FIG. 3), the reaction space height may have adjustability up to about 1 millimeter (i.e., the reaction space height can vary up to one millimeter, depending on the process performed). In various embodiments, for a spring comprising a coil spring (e.g., spring 440 in FIGS. 4A and 4B), or for a spring having more deflection potential or distance, the reaction space height may have adjustability up to about 9 millimeters (e.g., the reaction space height may range from 6-15 millimeters).

In various embodiments, a spring in a sealing system within a reaction chamber may comprise any suitable material, such as a metal or metal alloy (e.g., stainless steel or a nickel alloy). Previous sealing members used in a sealing system, such as an o-ring comprising a polymeric material, may stick, deform, or degrade at relatively lower temperatures (e.g., above 300° C.). Another previous sealing member, a diaphragm, may have higher defects in manufacturing, deformation at higher temperatures, and other problems that led to insufficient sealing between the lower and upper chambers within the reaction chamber volume. A spring comprising a metal material may have the benefits of have lower defects in manufacturing, less particle generation during processing, higher spring-back and yield strength (can be adjusted by adjusting the number of curls or convolutions of the spring), minimum deflection required to achieve at least a partial seal between components (allowing for the discussed flexibility and adjustability within the reaction chamber and reaction space height), higher temperature capabilities (e.g., above 800° C. in some cases), and the ability to easily create spring rings having different cross-sectional shapes based on the deflection needs for a particular deposition process.

In various embodiments, a reactor or reaction chamber may comprise a purge channel in fluid communication with the reaction chamber volume having an outlet proximate the spring. For example, with reference to FIGS. 4A and 4B, a reaction chamber may comprise a purge channel 420 in fluid connection with the reaction chamber volume (e.g., with reaction space 412). Purge channel 420 may be fluidly coupled to a purge gas source 414 (e.g., similar to purge gas source 14 in FIG. 1), which may comprise a purge gas (e.g., an inert or less reactive gas, such as nitrogen gas, helium, argon, or the like). Purge channel 420 may be disposed through the chamber sidewall and/or spacer plate 470. Thus, purge channel 420 may comprise an outlet into the reaction chamber proximate spring 440. Before, after, and/or during deposition steps in a deposition process, a purge gas may flow from purge gas source 414 through purge channel 420, and into the reaction chamber proximate spring 440 (e.g., between deposition steps, or steps involving reactant introduction into the reaction chamber). Such purging (e.g., near spring 440) may be configured to mitigate the risk of undesired deposition on spring 440.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A reaction chamber, comprising:
a reaction chamber volume enclosed within the reaction chamber;
a susceptor configured to support a substrate disposed in the reaction chamber volume, the susceptor being configured to translate up and down along an axis within the reaction chamber;
a reaction space above the susceptor within the reaction chamber volume;
a lower chamber space below the susceptor within the reaction chamber volume; and
a sealing system causing the reaction space and the lower chamber space to be at least partially fluidly separate, wherein the sealing system comprises:
a spacer plate surrounding the susceptor, wherein the susceptor is coupled to the spacer plate; and
a spring coupled to the spacer plate and the susceptor having a spring bias toward a compressed position or an extended position, such that the spring bias facilitates creation of at least a partial seal between the spacer plate and the susceptor, causing at least partial fluid separation between the reaction space and the lower chamber space as the susceptor moves up and down within the reaction chamber.

2. The reaction chamber of claim 1, wherein the sealing system further comprises a flow control ring disposed around the susceptor and disposed between the susceptor and the spacer plate, wherein the spring is disposed between the flow control ring and the spacer plate such that the spring is coupled to the susceptor via the flow control ring, wherein the at least partial seal between the spacer plate and the susceptor is facilitated by the spring bias between the flow control ring and the spacer plate.

3. The reaction chamber of claim 2, wherein the spring is disposed between an upward-facing surface of the flow control ring and a downward-facing surface of the spacer plate.

4. The reaction chamber of claim 3, wherein the spring is biased toward the extended position, such that a downward force from the spring is applied to the flow control ring, which creates a downward force on the susceptor, such that at least a partial seal is formed between the flow control ring and the susceptor, forming the at least partial fluid separation between the reaction space and the lower chamber space.

5. The reaction chamber of claim 2, wherein the spring forms at least a partial seal between the spring and the spacer plate, and between the spring and the flow control ring.

6. The reaction chamber of claim 5, wherein the spring is fixedly coupled to at least one of the spacer plate or the flow control ring.

7. The reaction chamber of claim 2, wherein the spring surrounds the susceptor, wherein the spring comprises a cross-sectional shape having at least one curl.

8. The reaction chamber of claim 7, wherein the cross-sectional shape of the spring comprises an E-shape having three curls.

9. The reaction chamber of claim 2, wherein the spring is disposed at a first point around the susceptor, wherein the reaction chamber further comprises a second spring disposed at a second point around the susceptor, such that a force on the susceptor resulting from the spring occurs at multiple points.

10. The reaction chamber of claim 2, further comprising a gas distribution device disposed above the susceptor in the reaction space, wherein the spring allows adjustment of a distance between the susceptor and the gas distribution device to be adjustable by up to nine millimeters while still maintaining the at least partial fluid separation between the reaction space and the lower chamber space.

11. The reaction chamber of claim 2, wherein the spring comprises at least one of a metal or metal alloy.

12. The reaction chamber of claim 11, wherein the spring comprises at least one of stainless steel or a nickel alloy.

13. A reactor system comprising the reaction chamber of claim 1.

14. The reaction reactor system of claim 13, further comprising a vacuum source in fluid communication with the lower chamber space.

15. A method, comprising:
translating a susceptor in a reaction chamber upwardly from a first position to a second position;
applying a force on a spring coupled between the susceptor and a spacer plate in response to the moving the susceptor, wherein the spring has a spring bias toward a compressed position or an extended position; and
maintaining at least a partial seal between the spacer plate and the susceptor during the moving the susceptor in response to the applying the force on the spring, such there is at least partial fluid separation between a reaction space above the susceptor and a lower chamber space below the susceptor in the reaction chamber.

16. The method of claim 15, further comprising:
causing a downward force on the susceptor via the spring bias, which facilitates the at least partial fluid separation between the reaction space and the lower chamber space.

17. The method of claim 16, wherein the force applied to the spring comprises a compression force, and wherein the spring bias is toward the extended position.

18. The method of claim 16, wherein the reaction chamber further comprises a flow control ring disposed between the susceptor and the spacer plate, wherein the spring is disposed between the flow control ring and the spacer plate such that the spring is coupled to the susceptor via the flow control ring.

19. The method of claim 18, further comprising:
moving an upward-facing surface of the flow control ring closer to a downward-facing surface of the spacer plate in response to the moving the susceptor, wherein the force applied on the spring is a compression force between the upward-facing surface of the flow control ring and the downward-facing surface of the spacer plate.

20. The method of claim 19, further comprising:
maintaining at least a partial seal between the spring and the spacer plate, and between the spring and the flow control ring, during the moving the susceptor.
